(19) United States
(12) Patent Application Publication
(10) Pub. No.: US 2024/0069182 A1
(43) Pub. Date: Feb. 29, 2024

(54) ULTRASONIC SIGNAL DETECTION CIRCUIT, ULTRASONIC SIGNAL DETECTION METHOD AND ULTRASONIC DETECTION APPARATUS

(71) Applicant: BOE TECHNOLOGY GROUP CO., LTD., Beijing (CN)

(72) Inventors: Liang CUI, Beijing (CN); Lei WANG, Beijing (CN); Yangbing LI, Beijing (CN); Yingzi WANG, Beijing (CN); Jiabin WANG, Beijing (CN); Yubo WANG, Beijing (CN); Yanling HAN, Beijing (CN)

(21) Appl. No.: 17/765,349

(22) PCT Filed: May 21, 2021
(86) PCT No.: PCT/CN2021/095156

§ 371 Date: Mar. 30, 2022

(51) Int. Cl. G01S 7/534

(52) U.S. Cl. CPC G01S 7/534; H03K 17/56

(57) ABSTRACT

The disclosure provides an ultrasonic signal detection circuit including a sensing circuit, a unidirectional conduction circuit and a source follower circuit. The sensing circuit is connected to an input terminal of the source follower circuit through the unidirectional conduction circuit; the sensing circuit is configured to generate a piezoelectric signal according to a received ultrasonic echo signal and output the piezoelectric signal to the unidirectional conduction circuit. The piezoelectric signal is an alternating current signal; the unidirectional conduction circuit is configured to rectify the alternating current signal to only allow a forward or a reverse current portion thereof to pass through. The forward/reverse current portion charges/discharges the input terminal of the source follower circuit after passing through the unidirectional conduction circuit. The source follower circuit is configured to generate a detection signal according to a voltage at its input terminal and output the detection signal through its output terminal.

### TECHNICAL FIELD

The present disclosure relates to the technical field of ultrasonic waves, and in particular, to an ultrasonic signal detection circuit, an ultrasonic signal detection method and an ultrasonic detection apparatus.

### BACKGROUND

Ultrasonic signal detection generally adopts a signal integration mode. Specifically, a sensing circuit generates a piezoelectric signal according to a received ultrasonic echo signal and outputs the piezoelectric signal, and the piezoelectric signal is integrated to obtain a corresponding integration voltage which may reflect an intensity of the ultrasonic echo signal.

### SUMMARY

The present disclosure intends to solve at least one of the technical problems of the prior art, and provides an ultrasonic signal detection circuit, an ultrasonic signal detection method and an ultrasonic detection apparatus.

In a first aspect, an embodiment of the present disclosure provides an ultrasonic signal detection circuit, including: a sensing circuit, a unidirectional conduction circuit and a source follower circuit, wherein the sensing circuit is connected to an input terminal of the source follower circuit through the unidirectional conduction circuit;
the sensing circuit is configured to generate a piezoelectric signal according to a received ultrasonic echo signal and output the piezoelectric signal to the unidirectional conduction circuit, wherein the piezoelectric signal is an alternating current signal;
the unidirectional conduction circuit is configured to rectify the alternating current signal to only allow a forward current portion or a reverse current portion of the alternating current signal to pass through, wherein the forward current portion is configured to charge the input terminal of the source follower circuit after passing through the unidirectional conduction circuit, and the reverse current portion is configured to discharge the input terminal of the source follower circuit after passing through the unidirectional conduction circuit; and
the source follower circuit is configured to generate a detection signal according to a voltage at the input terminal of the source follower circuit and output the detection signal through an output terminal of the source follower circuit.

In some embodiments, the unidirectional conduction circuit includes a diode; and a first terminal of the diode is connected to the sensing circuit, and a second terminal of the diode is connected to the input terminal of the source follower circuit.

In some embodiments, the source follower circuit includes a first transistor; and
a gate electrode of the first transistor is connected to the input terminal of the source follower circuit, a first terminal of the first transistor is connected to a first voltage supply terminal, and a second terminal of the second transistor is connected to the output terminal of the source follower circuit.

In some embodiments, the unidirectional conduction circuit is configured to allow the forward current portion of the alternating current signal to pass through, the first transistor is an N-type transistor, the first terminal of the diode is a positive terminal, and the second terminal of the diode is a negative terminal; or
the unidirectional conduction circuit is configured to allow the reverse current portion of the alternating current signal to pass through, the first transistor is a 1D-type transistor, the first terminal of the diode is a negative terminal, and the second terminal of the diode is a positive terminal.

In some embodiments, the ultrasonic signal detection circuit further includes a voltage regulation circuit, wherein the voltage regulation circuit is connected to the input terminal of the source follower circuit and a first control signal terminal; and
the unidirectional conduction circuit is configured to allow the forward current portion of the alternating current signal to pass through, and the voltage regulation circuit is configured to increase the voltage at the input terminal of the source follower circuit by a preset voltage value in response to a control of a first control signal from the first control signal terminal; or
the unidirectional conduction circuit is configured to allow the reverse current portion of the alternating current signal to pass through, and the voltage regulation circuit is configured to decrease the voltage at the input terminal of the source follower circuit by the preset voltage value in response to the control of the first control signal from the first control signal terminal.

In some embodiments, the voltage regulation circuit includes a capacitor; and
a first terminal of the capacitor is connected to the input terminal of the source follower circuit, and a second terminal of the capacitor is connected to the first control signal terminal.

In some embodiments, the ultrasonic signal detection circuit further includes a switching circuit and a reading signal line, wherein the switching circuit is connected to the output terminal of the source follower circuit and a second control signal terminal; and
the switching circuit is connected to a scan control signal terminal and is configured to control an electric connection/disconnection between the output terminal of the source follower circuit and the reading signal line in response to a control of a scan control signal from the scan control signal terminal.

In some embodiments, the switching circuit includes a second transistor; and
a gate electrode of the second transistor is connected to the second control signal terminal, a first electrode of the second transistor is connected to the output terminal of the source follower circuit, and a second electrode of the second transistor is connected to the reading signal line.

In some embodiments, the voltage regulation circuit is configured to increase the voltage at the input terminal of the source follower circuit by the preset voltage value in response to the control of the first control signal, the second transistor is an N-type transistor, and the first control signal terminal and the second control signal terminal are a same control signal terminal;
or, the voltage regulation circuit is configured to decrease the voltage at the input terminal of the source follower circuit by the preset voltage value in response to the control of the first control signal, the second transistor is a P-type transistor, and the first control signal terminal and the second control signal terminal are a same control signal terminal: and
the preset voltage value is equal to a voltage difference between a high level voltage and a low level voltage of the second control signal.

In some embodiments, the ultrasonic signal detection circuit further includes a reset circuit;
wherein the reset circuit is connected to the input terminal of the source follower circuit, a reset voltage supply terminal and a reset control signal terminal, and is configured to write a reset voltage from the reset voltage supply terminal to the input terminal of the source follower circuit in response to a control of a reset control signal from the reset control signal terminal.
In some embodiments, the reset circuit includes a third transistor; and a gate electrode of the third transistor is connected to the reset control signal terminal, a first electrode of the third transistor is connected to the input terminal of the source follower circuit, and a second electrode of the third transistor is connected to the reset voltage supply terminal.

In some embodiments, the sensing circuit includes an ultrasonic sensor, a first terminal of the ultrasonic sensor is connected to a second voltage supply terminal, and a second terminal of the ultrasonic sensor is connected to the unidirectional conduction circuit; and
the second voltage supply terminal is configured to provide a reference voltage to the first terminal of the ultrasonic sensor during a signal acquisition phase.

In some embodiments, the unidirectional conduction circuit is configured to allow the forward current portion of the alternating current signal to pass through, the reference voltage is equal to V0; or,
the unidirectional conduction circuit is configured to allow the reverse current portion of the alternating current signal to pass through, and the reference voltage is equal to −V0; and
V0 is a forward conduction voltage drop of the unidirectional conduction circuit, where V0 is greater than 0.

In some embodiments, the second voltage supply terminal is further configured to provide a driving signal to the first terminal of the ultrasonic sensor during an ultrasonic emission phase.

In a second aspect, an embodiment of the present disclosure further provides an ultrasonic detection apparatus, including a carrier structure and the ultrasonic signal detection circuit according to the first aspect above, wherein the ultrasonic signal detection circuit is on the carrier structure.

In a third aspect, an embodiment of the present disclosure further provides an ultrasonic signal detection method, which is based on the ultrasonic signal detection circuit according to the first aspect above, the ultrasonic signal detection method including:
in a signal acquisition phase, generating a piezoelectric signal according to a received ultrasonic echo signal and outputting the piezoelectric signal to the unidirectional conduction circuit, by the sensing circuit, and rectifying, by the unidirectional conduction circuit, the alternating current signal so as to only allow a forward current portion or a reverse current portion of the alternating current signal to pass through; and
in an output phase, generating a detection signal according to a voltage at the input terminal of the source follower circuit, and outputting the detection signal through an Output terminal of the source follower circuit, by the source follower circuit.

In some embodiments, in the signal acquisition phase, the unidirectional conduction circuit only allows the forward current portion of the alternating current signal to pass through, and between the signal acquisition phase and the output phase, the ultrasonic signal detection method further includes:
in a voltage regulation phase, increasing, by the voltage regulation circuit, the voltage at the input terminal of the source follower circuit by the preset voltage value in response to the control of the first control signal provided by the first control signal terminal; or
in the signal acquisition phase, the unidirectional conduction circuit only allows the reverse current portion of the alternating current signal to pass through, and between the signal acquisition phase and the output phase, the ultrasonic signal detection method further includes:
in the voltage regulation phase, decreasing, by the voltage regulation circuit, the voltage at the input terminal of the source follower circuit by the preset voltage value in response to the control of the first control signal provided by the first control signal terminal.

In some embodiments, before the signal acquisition phase, the ultrasonic signal detection method further includes:
in a reset phase, writing, by the reset circuit, the reset voltage provided by the reset voltage supply terminal to the input terminal of the source follower circuit in response to the control of the reset control signal provided by the reset control signal terminal.

### BRIEF DESCRIPTION OF DRAWINGS

FIG. 1 is a schematic diagram illustrating a circuit structure of an ultrasonic signal detection circuit in the related art;

FIG. 2 is a timing diagram illustrating an operation of the ultrasonic signal detection circuit shown in FIG. 1;

FIG. 3 is a schematic diagram illustrating variation of integration voltage with increase of integration time in the related art;

FIG. 4 is a schematic diagram illustrating a circuit structure of an ultrasonic signal detection circuit according to an embodiment of the present disclosure;

FIG. 5 is a schematic diagram illustrating variation of integration voltage with increase of integration time according to an embodiment of the present disclosure;

FIG. 6 is schematic diagram illustrating another circuit structure of an ultrasonic signal detection circuit according to an embodiment of the present disclosure;

FIG. 7 is schematic diagram illustrating another circuit structure of an ultrasonic signal detection circuit according to an embodiment of the present disclosure;

FIG. 8 is schematic diagram illustrating another circuit structure of an ultrasonic signal detection circuit according to an embodiment of the present disclosure;

FIG. 9 is a schematic diagram illustrating another circuit structure of an ultrasonic signal detection circuit according to an embodiment of the present disclosure;

FIG. 10 is schematic diagram illustrating another circuit structure of an ultrasonic signal detection circuit according to an embodiment of the present disclosure;

FIG. 11 is schematic diagram illustrating another circuit structure of an ultrasonic signal detection circuit according to an embodiment of the present disclosure;

FIG. 12 is a timing diagram illustrating an operation of the ultrasonic signal detection circuit shown in FIG. 10;

FIG. 13 is schematic diagram illustrating another circuit structure of an ultrasonic signal detection circuit according to an embodiment of the present disclosure;

FIG. 14 is a flowchart illustrating an ultrasonic signal detection method according to an embodiment of the present disclosure; and

FIG. 15 is a flowchart illustrating another ultrasonic signal detection method according to an embodiment of the present disclosure.

### DETAIL DESCRIPTION OF EMBODIMENTS

In order to enable one of ordinary skill in the art to better understand the technical solutions of the present disclosure, an ultrasonic signal detection circuit, an ultrasonic signal detection method and an ultrasonic detection apparatus according to the present disclosure are described in detail below with reference to the accompanying drawings.

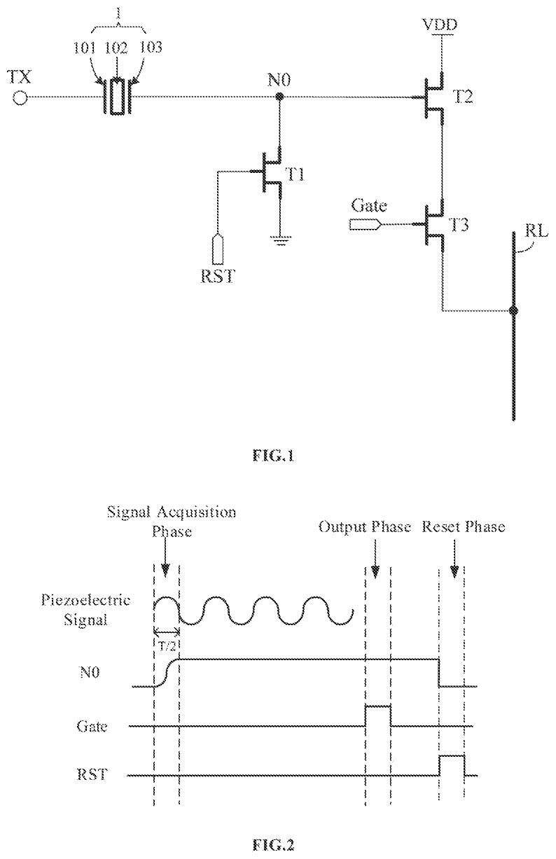

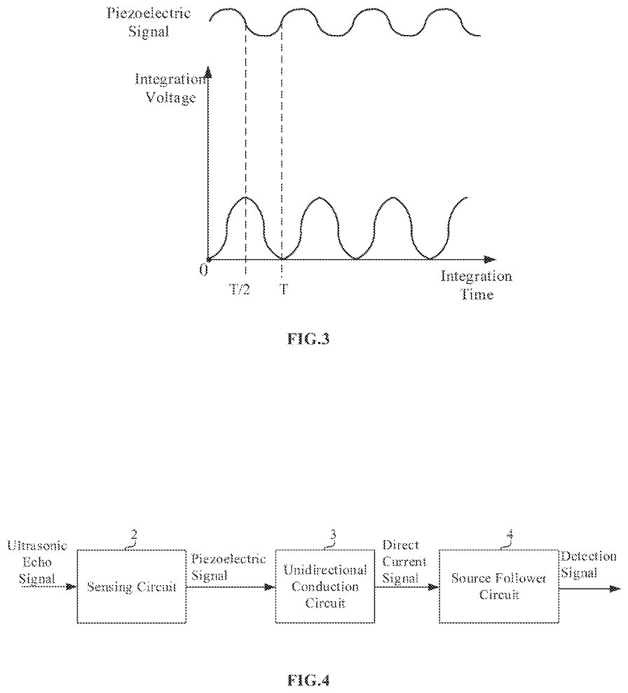

FIG. 1 is a schematic diagram illustrating a circuit structure of an ultrasonic signal detection circuit in the related art, and FIG. 2 is a timing diagram illustrating an operation of the ultrasonic signal detection circuit shown in FIG. 1. As shown in FIGS. 1 and 2, the ultrasonic signal detection circuit in the related art includes three transistors T1, T2, and T3, and an ultrasonic sensor 1. The ultrasonic sensor 1 includes a driving electrode 101, a piezoelectric material layer 102, and a receiving electrode 103. The driving electrode 101 is connected to a driving voltage supply terminal TX, and the receiving electrode 103 is connected to a gate electrode of the transistor T2; the transistor T1 is controlled by a signal terminal RST, and the transistor T3 is controlled by a signal terminal Gate.

In a signal acquisition phase, the driving voltage supply terminal TX supplies a constant voltage (generally, ground voltage Vss) to the driving electrode 101, the ultrasonic sensor 1 receives an ultrasonic echo signal, and outputs a piezoelectric signal through the receiving electrode 103 based on a positive piezoelectric effect. The piezoelectric signal is an alternating current signal, the time (duration) of a forward current portion (component) and the time of a reverse current portion of the alternating current signal are substantially equal, and the alternating current signal is generally a sine wave signal or an approximate sine wave signal. The alternating current signal output by the receiving electrode 103 changes a voltage at the gate electrode of the transistor T2. Specifically, the forward current portion of the alternating current signal may charge the gate electrode of the transistor T2, and the reverse current portion may discharge the gate electrode of the transistor T2. That is, the forward current component may cause an integration voltage to increase, while the reverse current component may cause the integration voltage to decrease.

FIG. 3 is a schematic diagram illustrating variation of integration voltage with increase of integration time in the related art. As shown in FIG. 3, the detailed description is given in a case where the integration time is in an interval of [0, T]. The integration voltage gradually increases when the integration time is an interval of [0, T/2l, and the integration voltage gradually decreases when the integration time is in an interval of (T/2, T], where T is a cycle (period) of the piezoelectric signal output by the ultrasonic sensor 1 (also a cycle of the ultrasonic echo signal). Based on the above situation, the integration time is often set to T/2 to obtain the maximum integration voltage, and variation of the integration voltage at a node NO may be seen in FIG. 3.

However, in practical applications, it is found that in the related art, a magnitude of the integration voltage obtained by directly integrating the piezoelectric signal in the interval of [0, T/2] is not great enough, and a signal quantity of a detection signal (transmitted from a reading signal line RL) output by the ultrasonic signal detection circuit based on the integration voltage is still small, so that it is difficult to accurately determine the intensity of the ultrasonic echo signal. In addition, only the portion of the ultrasonic echo signal corresponding to T/2 is used, and thus, the utilization rate is low.

In order to solve at least one technical problem in the related art, an embodiment of the present disclosure provide a corresponding solution.

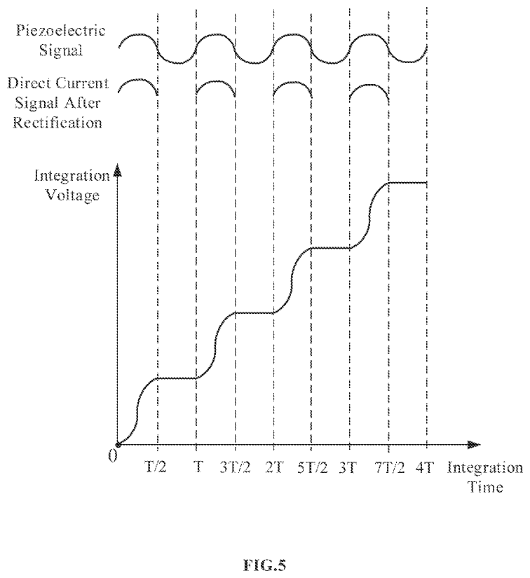

FIG. 4 is a schematic diagram illustrating a circuit structure of an ultrasonic signal detection circuit according to an embodiment of the present disclosure. As shown in FIG. 4, the ultrasonic signal detection circuit includes a sensing circuit 2, an unidirectional conduction circuit 3 and a source follower circuit 4. The sensing circuit 2 is connected to an input terminal of the source follower circuit 4 through the unidirectional conduction circuit 3.

The sensing circuit 2 is configured to generate a piezoelectric signal according to a received ultrasonic echo signal, and output the piezoelectric signal to the unidirectional conduction circuit 3, where the piezoelectric signal is an alternating current signal.

The unidirectional conduction circuit 3 is configured to rectify the alternating current signal to allow only a forward current portion or a reverse current portion of the alternating current signal to pass through, the forward current portion may charge the input terminal of the source follower circuit 4 after passing through the unidirectional conduction circuit 3, and the reverse current portion may discharge the input terminal of the source follower circuit 4 after passing through the unidirectional conduction circuit 3.

The source follower circuit 4 is configured to generate a detection signal according to a voltage at the input terminal thereof and output the detection signal through an output terminal thereof.

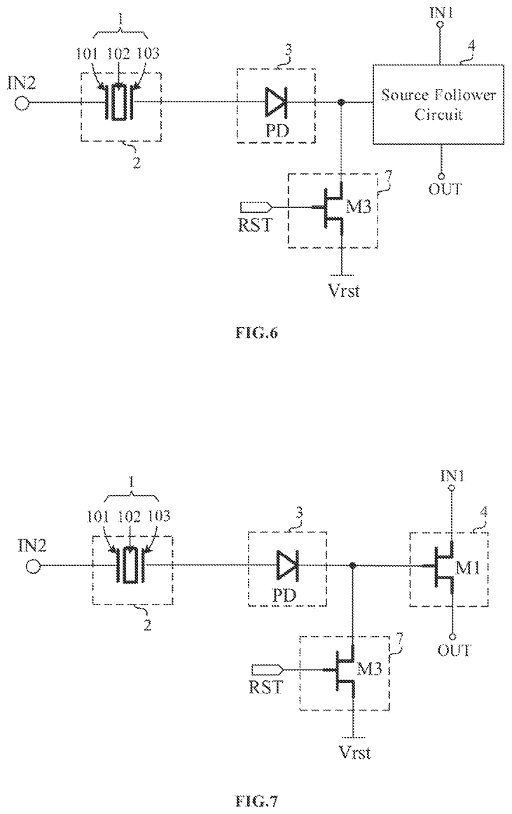

FIG. 5 is a schematic diagram illustrating variation of integration voltage with increase of integration time according to an embodiment of the present disclosure. As shown in FIG. 5, as an example, in a case where the unidirectional conduction circuit 3 only allows the forward current portion of the alternating current signal to pass through, the signal output by the unidirectional conduction circuit 3 is an intermittent direct current signal. With the increase of the integration time, the integration voltage (positive voltage) at the input terminal of the source follower circuit 4 increases in a step-like manner. Therefore, for the ultrasonic signal detection circuit according to an embodiment of the present disclosure, the integration time is no longer limited to T/2, but may be longer than T/2, for example, 2T, 3T, 4T or even longer. In this way, a greater integration voltage may be obtained, so that the utilization rate of the ultrasonic echo signal can be effectively improved, and the signal quantity of a finally output detection signal can be improved.

Similarly, in a case where the unidirectional conduction circuit 3 only allows the reverse current portion of the alternating current signal to pass through, the integration voltage (negative voltage) at the input terminal of the source follower circuit 4 decreases in a step-like manner with the increase of the integration time, and the magnitude of the integration voltage increases in a step-like manner, so that the utilization rate of the ultrasonic echo signal can be effectively improved, and the signal quantity of the finally output detection signal can be improved.

FIG. 6 is schematic diagram illustrating another circuit structure of an ultrasonic signal detection circuit according to an embodiment of the present disclosure. As shown in FIG. 6, in some embodiments, the unidirectional conduction circuit 3 includes a diode PD. A first terminal of the diode PD is connected to the sensing circuit 2, and a second terminal of the diode PD is connected to the input terminal of the source follower circuit 4.

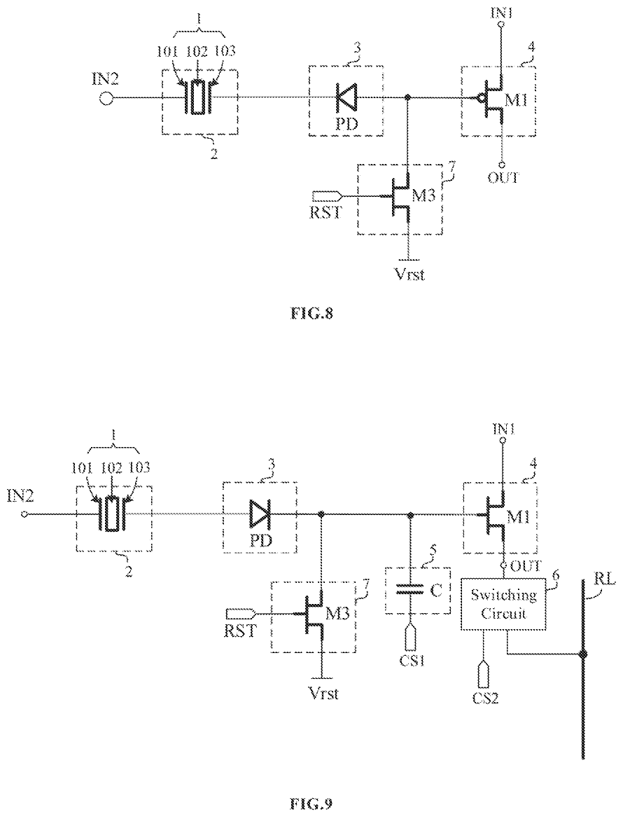

FIG. 7 is schematic diagram illustrating another circuit structure of an ultrasonic signal detection circuit according to an embodiment of the present disclosure. As shown in FIG. 7, in some embodiments, the source follower circuit 4 includes a first transistor M1. A gate electrode of the first transistor M1 is connected to the input terminal of the source follower circuit 4, a first terminal of the first transistor M1 is connected to a first voltage supply terminal IN1, and a second terminal of the second transistor M2 is connected to the output terminal OUT of the source follower circuit 4.

In some embodiments, the unidirectional conduction circuit 3 is configured to allow the forward current portion of the alternating current signal to pass through, the first transistor M1 is an N-type transistor, the first terminal of the diode PD is a positive terminal, and the second terminal of the diode PD is a negative terminal.

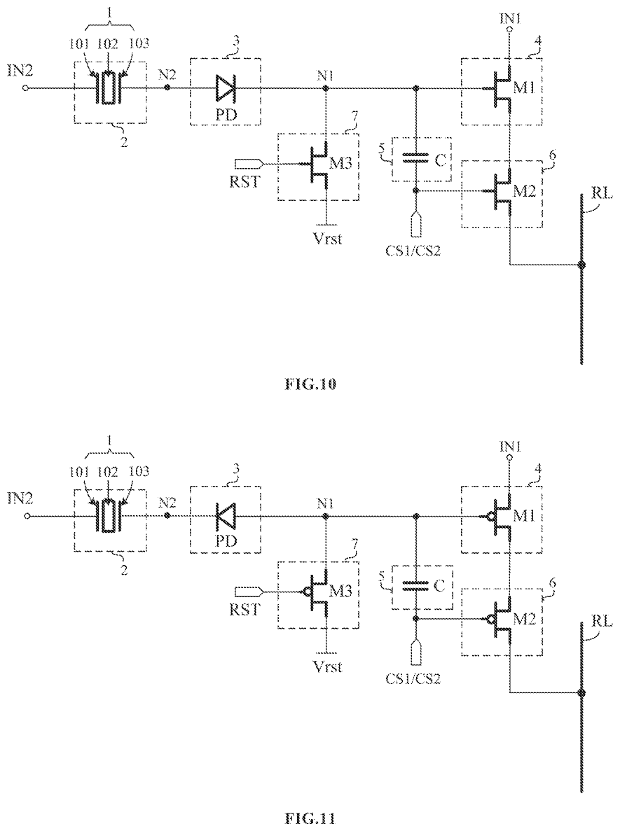

FIG. 8 is schematic diagram illustrating another circuit structure of an ultrasonic signal detection circuit according to an embodiment of the present disclosure. As shown in FIG. 8, unlike the case shown in FIG. 7, the unidirectional conduction circuit 3 in FIG. 8 is configured to allow the reverse current portion of the alternating current signal to pass through, the first transistor M1 is a P-type transistor, the first terminal of the diode PD is a negative terminal, and the second terminal of the diode PD is a positive terminal.

FIG. 9 is a schematic diagram illustrating another circuit structure of an ultrasonic signal detection circuit according to an embodiment of the present disclosure. As shown in FIG. 9, in some embodiments, the ultrasonic signal detection circuit further includes a voltage regulation circuit 5 connected to the input terminal of the source follower circuit 4 and a first control signal terminal CS In a case where the unidirectional conduction circuit 3 is configured to allow the forward current portion of the alternating current signal to pass through, the voltage regulation circuit 5 is configured to increase the voltage at the input terminal of the source follower circuit 4 by a preset voltage value in response to a control of a first control signal provided by the first control signal terminal CS1.

In a case where the unidirectional conduction circuit 3 is configured to allow the reverse current portion of the alternating current signal to pass through, the voltage regulation circuit 5 is configured to decrease the voltage at the input terminal of the source follower circuit 4 by the preset voltage value in response to the control of the first control signal provided by the first control signal terminal CS1.

In some embodiments, the voltage regulation circuit 5 includes a capacitor C. A first terminal of the capacitor C is connected to the input terminal of the source follower circuit 4, and a second terminal of the capacitor C is connected to the first control signal terminal CS1. The first control signal provided by the first control signal terminal CS1 may jump between a preset high level voltage and a preset low level voltage (a voltage difference between the high level voltage and the low level voltage is equal to the preset voltage value), so as to increase or decrease the voltage at the input terminal of the source follower circuit 4 by the preset voltage value through a bootstrap action of the capacitor C.

In some embodiments, the ultrasonic signal detection circuit further includes a switching circuit 6 and a reading signal line RL. The switching circuit 6 is connected to the output terminal OUT of the source follower circuit 4 and the second control signal terminal CS2, respectively. The switching circuit 6 is connected to a scan control signal terminal, and the switching circuit 6 is configured to control an electric connection/disconnection between the output terminal OUT of the source follower circuit 4 and the reading signal line RL in response to a control of a scan control signal provided by the scan control signal terminal.

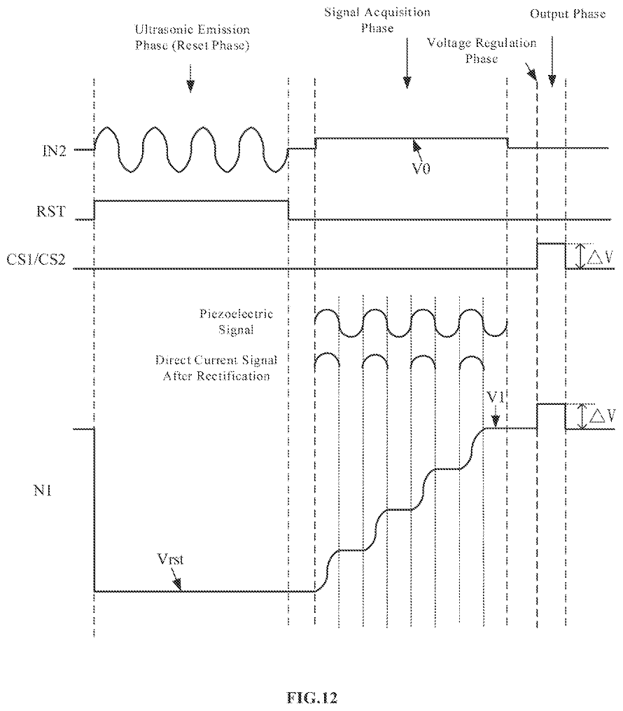

FIG. 10 is schematic diagram illustrating another circuit structure of an ultrasonic signal detection circuit according to an embodiment of the present disclosure. As shown in FIG. 10, in some embodiments, the switching circuit 6 includes a second transistor M2. A gate electrode of the second transistor M2 is connected to the second control signal terminal CS2, a first electrode of the second transistor M2 is connected to the output terminal of the source follower circuit 4, and a second electrode of the second transistor M2 is connected to the reading signal line RL.

In some embodiments, the voltage regulation circuit 5 is configured to increase the voltage at the input terminal of the source follower circuit 4 by the preset voltage value in response to the control of the first control signal (i.e., the unidirectional conduction circuit 3 is configured to allow the forward current portion of the alternating current signal to pass through). The second transistor M2 is an N-type transistor. The first control signal terminal CS1 and the second control signal terminal CS2 are a same control signal terminal. The preset voltage value is equal to a voltage difference between a high level voltage and a low level voltage of the second control signal.

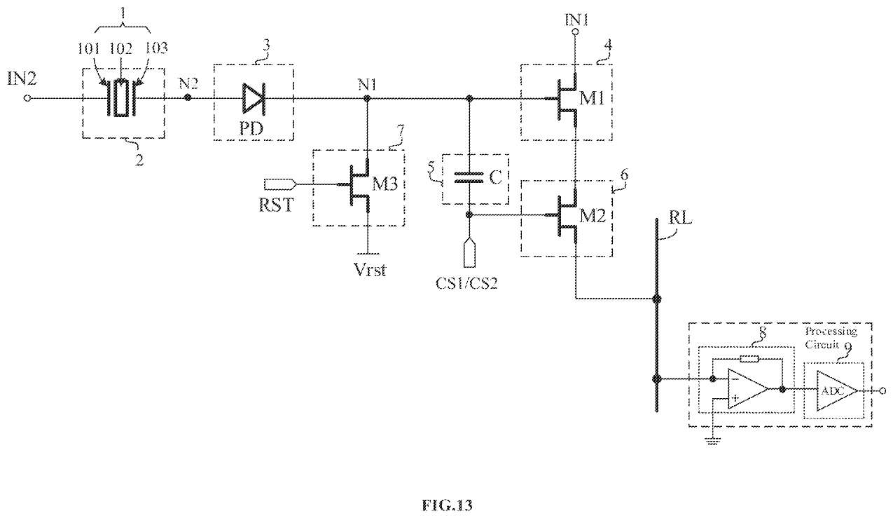

FIG. 11 is schematic diagram illustrating another circuit structure of an ultrasonic signal detection circuit according to an embodiment of the present disclosure. As shown in FIG. 11, unlike the case shown in FIG. 10, the voltage regulation circuit 5 in FIG. 11 is configured to decrease the voltage at the input terminal of the source follower circuit 4 by the preset voltage value in response to the control of the first control signal (i.e., the unidirectional conduction circuit 3 is configured to allow the reverse current portion of the alternating current signal to pass through). The second transistor M2 is a P-type transistor. The first control signal terminal CS1 and the second control signal terminal CS2 are a same control signal terminal. The preset voltage value is equal to the voltage difference between the high level voltage and the low level voltage of the second control signal.

In the embodiments shown in FIGS. 10 and 11, the first control signal terminal CS1 and the second control signal terminal CS2 are a same control signal terminal, so that the number of control signal terminals can be effectively reduced, thereby simplifying the circuit structure.

Referring to FIGS. 4, 6 to 11, in some embodiments, the ultrasonic signal detection circuit further includes a reset circuit 7. The reset circuit 7 is connected to the input terminal of the source follower circuit 4, a reset voltage supply terminal, and a reset control signal terminal RST. The reset circuit 7 is configured to write a reset voltage provided by the reset voltage supply terminal Vrst to the input terminal of the source follower circuit in response to a control of the reset control signal provided by the reset control signal terminal RST.

In some embodiments, the reset circuit 7 includes a third transistor M3, A gate electrode of the third transistor M3 is connected to the reset control signal terminal RST, a first electrode of the third transistor M3 is connected to the input terminal of the source follower circuit 4, and a second electrode of the third transistor M3 is connected to the reset voltage supply terminal.

Referring to FIGS. 4, and 6 to 11, in some embodiments, the sensing circuit 2 includes an ultrasonic sensor 1. A first terminal of the ultrasonic sensor 1 is connected to a second voltage supply terminal IN2, and a second terminal of the ultrasonic sensor 1 is connected to the unidirectional conduction circuit 3. The second voltage supply terminal IN2 is configured to supply a reference voltage to the first terminal of the ultrasonic sensor 1 during the signal acquisition phase.

Alternatively, the ultrasonic sensor 1 includes: a driving electrode 101, a piezoelectric material layer 102, and a receiving electrode 103. The driving electrode 101 serves as the first terminal of the ultrasonic sensor 1, and the receiving electrode serves as the second terminal of the ultrasonic sensor 1. The operation principle of the ultrasonic sensor 1 is as follows:

In an ultrasonic emission phase, a driving signal (for example, a sine wave signal) may be applied to the driving electrode 101, and a constant voltage is applied to the receiving electrode 103, so that an inverse piezoelectric effect occurs in the piezoelectric material layer 102 due to a voltage excitation, which causes the piezoelectric material layer 102 to emit an ultrasonic wave. The emitted ultrasonic wave is reflected when contacting an object (for example, a finger), and an ultrasonic echo wave is generated. A distance between the object and the ultrasonic sensor 1 varies, so that the vibration intensity of the ultrasonic echo wave generated by reflection varies (a frequency of the ultrasonic echo wave is the same as or substantially the same as a frequency of the ultrasonic wave emitted in the emission phase). In the signal acquisition phase, the driving signal is stopped being applied to the driving electrode 101, and the constant voltage (for example, the reference voltage provided by the second voltage supply terminal IN2) is applied to the driving electrode 101, and the constant voltage is stopped being applied to the receiving electrode 103, so that the piezoelectric material layer 102 is affected by the ultrasonic echo wave, and a piezoelectric signal (an alternating current signal, specifically a sine wave signal or an approximate sine wave signal) is generated, at the receiving electrode 103 due to a positive piezoelectric effect.

In some embodiments, a piezoelectric material of the piezoelectric material layer 102 includes polyvinylidene fluoride (PVDF). The polyvinylidene fluoride has advantages of difficult breakage, waterproofness, capability of being continuously drawn in large quantities, low price, wide frequency response range and the like. It should be noted that the piezoelectric material of the piezoelectric material layer 102 may be a piezoelectric single crystal, a piezoelectric ceramic, or the like. The piezoelectric single crystal may include, for example, quartz (SiO2), lithium niobate (LiNbO3), or the like. The piezoelectric ceramic may include, for example, barium titanate (BaTiO3), lead zirconate titanate (Pb(ZritxTix)O3), or the like.

In some embodiments, the unidirectional conduction circuit 3 is configured to allow the forward current portion of the alternating current signal to pass through, and the reference voltage is equal to V0. Alternatively, the unidirectional conduction circuit 3 is configured to allow the reverse current portion of the alternating current signal to pass through, and the reference voltage is equal to −V0. V0 is a forward conduction voltage drop of the unidirectional conduction circuit 3, and V0 is greater than 0.

In some embodiments, the second voltage supply terminal IN2 is further configured to provide a driving signal to the first terminal of the ultrasonic sensor 1 during the ultrasonic emission phase.

The operation procedure of the ultrasonic signal detection circuit shown in FIG. will be described in detail below by taking the ultrasonic signal detection circuit shown in FIG. 10 as an example. The third transistor M3 in FIG. 10 is an N-type transistor, and the first voltage supply terminal IN1 provides a supply voltage VDD.

FIG. 12 is a timing diagram illustrating an operation of the ultrasonic signal detection circuit shown in FIG. 10. As shown in FIG. 12, the operation of the ultrasonic signal detection circuit may specifically include the following phases:

In an ultrasonic emission phase (also referred to as a reset phase), the second voltage supply terminal IN2 supplies a driving signal (a sine wave signal, 4 cycles are exemplarily shown), the reset control signal terminal RST supplies a high level voltage, and the second control signal terminal CS2 supplies a low level voltage.

When the reset control signal is in a high level state, the third transistor M3 is turned on, and the reset voltage Vrst (generally, having the magnitude of OV) is written into a node N1 to reset the input terminal of the source follower circuit 4, and a node N2 is discharged through the node N1. The diode PD has a forward conduction voltage drop, so that a voltage at the node N2 is maintained at V0. That is, a constant voltage is applied to the receiving electrode 103 in the ultrasonic sensor 1. The ultrasonic sensor 1 transmits ultrasonic waves outward under the action of the driving signal and the constant voltage.

In a signal acquisition phase, the second voltage supply terminal IN2 provides the reference voltage V0, the reset control signal terminal RST provides a low level voltage, and the second control signal terminal CS2 provides a low level voltage.

The reset control signal is in a low level state, and the third transistor M3 is turned off. The sensing circuit 2 receives the ultrasonic echo signal and outputs a corresponding piezoelectric signal to the node N2, where the piezoelectric signal is an alternating current signal, and a voltage corresponding to the forward current portion of the alternating current signal is greater than VU, and a voltage corresponding to the reverse current portion of the alternating current signal is less than V0. The unidirectional conduction circuit 3 (diode PD) rectifies the alternating current signal to allow only the forward current portion to pass through, and the voltage at the node increases in a step-like manner. At the end of the signal acquisition phase, the integration voltage at the node N1 is denoted as V1.

It should be noted that in an embodiment of the present disclosure, a duration of the signal acquisition phase is determined by a duration that the second voltage supply terminal IN2 provides the reference voltage VU. FIG. 12 only illustrates that the duration of the signal acquisition phase is 4 cycles of the ultrasonic echo signal, which is exemplary and does not limit the technical solution of the present disclosure.

In a voltage regulation phase, the second voltage supply terminal IN2 provides a low level voltage (generally, ground voltage), the reset control signal terminal RST provides a low level voltage, and the voltage provided by the second control signal terminal CS2 is changed from a low level voltage to a high level voltage.

The voltage at the second terminal of the capacitor C is changed from a low level voltage to a high level voltage, that is, is increased by a preset voltage value ΔV. Under the bootstrap action of the capacitor C, the voltage at the node N1 is also increased by the preset voltage value ΔV, that is, the voltage at the node N1 is V1+ΔV, so that the magnitude of the integration voltage is increased, the first transistor M1 may operate in an amplification state in an output phase, thereby increasing the signal quantity of the finally output detection signal.

In the output phase, the second voltage supply terminal IN2 provides a low level voltage (generally, ground voltage), the reset control signal terminal RST provides a low level voltage, and the second control signal terminal CS2 provides a high level voltage.

Since the second control signal terminal CS2 is in a high level state, the second transistor M2 is turned on. Accordingly, the first transistor M1 is also turned on, and the first transistor M1 outputs a corresponding detection signal according to the voltage at the node N1, the detection signal is transmitted to the reading signal line RI, through the second transistor M2 for further processing.

It should be noted that the operation process of the ultrasonic signal detection circuit shown in FIG. 11 is similar to that shown in FIG. 10, Specifically, the voltage at the node N1 in the ultrasonic signal detection circuit shown in FIG. 11 decreases in a step-like manner in the signal acquisition phase, and the voltage at the node N1 in the ultrasonic signal detection circuit shown in FIG. 11 decreases by the preset voltage value ΔV in the voltage regulation phase, which is not repeated herein.

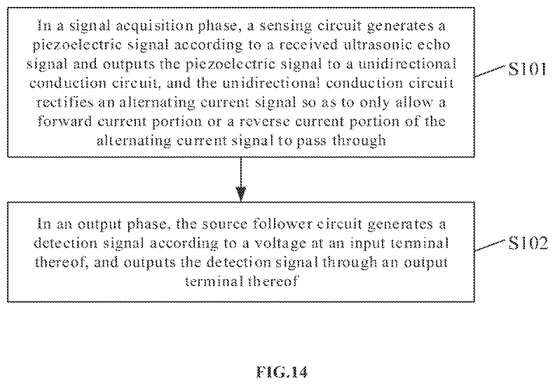

FIG. 13 is schematic diagram illustrating another circuit structure of an ultrasonic signal detection circuit according to an embodiment of the present disclosure. As shown in FIG. 13, unlike the previous embodiments, a processing circuit for further processing the detection signal is further provided in the embodiment shown in FIG. 13. The processing circuit may be used to further process the detection signal for subsequent acquisition. In some embodiments, the processing circuit may include a current-voltage conversion circuit 8, a signal amplification circuit 9, and the like. The current-voltage conversion circuit 8 may perform a current-voltage conversion processing on the detection signal, and the signal amplification circuit 9 may perform an amplification processing on the detection signal subjected to the current-voltage conversion processing. The specific circuit configurations of the current-voltage conversion circuit 8 and the signal amplification circuit 9 are not limited in the present disclosure.

It should be noted that it is only exemplary that the processing circuit includes the current-voltage conversion circuit 8 and the signal amplification circuit 9 in an embodiment of the present disclosure. In practical applications, other circuits having corresponding functions are further provided according to actual needs.

Based on the same inventive concept, an embodiment of the present disclosure further provides an ultrasonic detection apparatus, wherein the ultrasonic detection apparatus includes a carrier structure and an ultrasonic signal detection circuit located on the carrier structure, and the ultrasonic signal detection circuit may be the ultrasonic signal detection circuit according to the above embodiments.

As an alternative embodiment, the ultrasonic signal detection circuit may be applied to fingerprint recognition. More specifically, the ultrasonic detection apparatus is a display panel having an ultrasonic detection function, from which fingerprint recognition may be implemented in the display panel. In this case, the carrier structure may be a display panel, and the ultrasonic signal detection circuit may be disposed outside the display panel or may be integrated inside the display panel.

The display panel may be applied to any product or component with a display function, such as a mobile phone, a tablet computer, a television, a monitor, a laptop, a digital photo frame, a navigator and the like.

Alternatively, the ultrasonic signal detection circuit of the present disclosure may also be applied to other ultrasonic applications such as ultrasonic space positioning, ultrasonic medical treatment and the like. Accordingly, the ultrasonic detection apparatus may be specifically an ultrasonic space positioning apparatus, an ultrasonic medical apparatus, or the like.

It should be noted that different structural features in the ultrasonic signal detection circuit according to the above embodiments may be combined with each other, and the ultrasonic signal detection circuit obtained by combining the structural features also falls within the protection scope of the present disclosure.

Based on the same inventive concept, an embodiment of the present disclosure also provides an ultrasonic signal detection method, which is based on the ultrasonic signal detection circuit according to the above embodiments. The following description will be made with reference to the accompanying drawings.

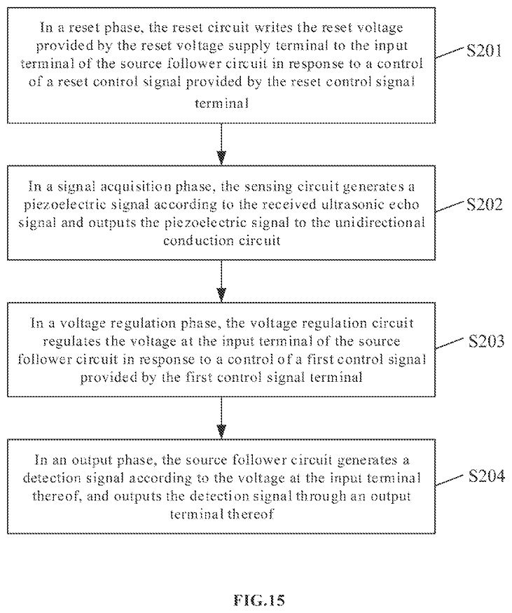

FIG. 14 is a flowchart illustrating an ultrasonic signal detection method according to an embodiment of the present disclosure. As shown in FIG. 14, the ultrasonic signal detection method includes:

Step S101, in a signal acquisition phase, a sensing circuit generates a piezoelectric signal according to a received ultrasonic echo signal and outputs the piezoelectric signal to a unidirectional conduction circuit, and the unidirectional conduction circuit rectifies an alternating current signal so as to only allow a forward current portion or a reverse current portion of the alternating current signal to pass through.

Step S102, in an output phase, the source follower circuit 4 generates a detection signal according to a voltage at an input terminal thereof, and outputs the detection signal through an output terminal thereof.

For the specific description of the step S101 and the step S102, reference may be made to corresponding contents in the foregoing embodiments, and details are not repeated here,

FIG. 15 is a flowchart illustrating another ultrasonic signal detection method according to an embodiment of the present disclosure. As shown in FIG. 15, the ultrasonic signal detection circuit is provided with not only the sensing circuit, the unidirectional conduction circuit, and the source follower circuit 4, but also a reset circuit and a voltage regulation circuit. The ultrasonic signal detection method includes the following steps:

Step S201, in a reset phase, the reset circuit writes a reset voltage provided by a reset voltage supply terminal to the input terminal of the source follower circuit in response to a control of a reset control signal provided by a reset control signal terminal.

Step S202, in a signal acquisition phase, the sensing circuit generates a piezoelectric signal according to the received ultrasonic echo signal and outputs the piezoelectric signal to the unidirectional conduction circuit.

Step S203, in a voltage regulation phase, the voltage regulation circuit regulates the voltage at the input terminal of the source follower circuit 4 in response to a control of a first control signal provided by a first control signal terminal.

If the unidirectional conduction circuit only allows the forward current portion of the alternating current signal to pass through, in step S203, the voltage regulation circuit increases the voltage at the input terminal of the source follower circuit 4 by a preset voltage value in response to the control of the first control signal provided by the first control signal terminal.

If the unidirectional conduction circuit only allows the reverse current portion of the alternating current signal to pass through, in step S203, the voltage regulation circuit decreases the voltage at the input terminal of the source follower circuit 4 by the preset voltage value in response to the control of the first control signal provided by the first control signal terminal.

Step S204, in an output phase, the source follower circuit 4 generates a detection signal according to the voltage at the input terminal thereof, and outputs the detection signal through an output terminal thereof.

For the specific description of the steps S201 to S204, reference may be made to the corresponding contents in the foregoing embodiments, and details are not repeated here. It should be noted that in some embodiments, the step S201 or the step S203 may not be performed, which also belongs to the protection scope of the present disclosure.

One of ordinary skill in the art should appreciate that the embodiments described in the specification are optional embodiments, and the actions and structures involved are not necessarily required for the claimed invention.

The embodiments in the present specification are all described in a progressive manner, and each embodiment focuses on differences between the embodiment and other embodiments, and portions that are the same and similar among the embodiments may be referred to each other.

Finally, it should further be noted that in this document, relational terms such as “first”, “second”, and the like are used solely to distinguish one entity or action from another entity or action without necessarily requiring or implying any actual such relationship or order between such entities or actions. Furthermore, the term “comprises” “comprising”, or any other variation thereof, is intended to cover a non-exclusive inclusion, such that a process, method, article, or apparatus that includes a list of elements does not include only those elements but may include other elements not expressly listed or inherent to such process, method, article, or apparatus. Without further limitation, an element described by the phrase “comprising a . . . ” does not exclude the presence of other like elements in a process, method, article, or apparatus that includes the element.

The above detailed description is provided for the ultrasonic signal detection circuit, the ultrasonic signal detection method and the ultrasonic detection apparatus according to the present disclosure, and the principle and the implementation mode of the present disclosure are explained by applying specific examples, and the description of the above embodiments is only used to understand the method and the core idea of the present disclosure. Meanwhile, for one of ordinary skill in the art, according to the idea of the present disclosure, the specific embodiments and the application range may be changed. In summary, the content of the present specification should not be construed as a limitation to the present disclosure.

1. An ultrasonic signal detection circuit, comprising a sensing circuit, a unidirectional conduction circuit and a source follower circuit, wherein
the sensing circuit is connected to an input terminal of the source follower circuit through the unidirectional conduction circuit;
the sensing circuit is configured to generate a piezoelectric signal according to a received ultrasonic echo signal and output the piezoelectric signal to the unidirectional conduction circuit, wherein the piezoelectric signal is an alternating current signal;
the unidirectional conduction circuit is configured to rectify the alternating current signal to only allow a forward current portion or a reverse current portion of the alternating current signal to pass through, wherein the forward current portion is configured to charge the input terminal of the source follower circuit after passing through the unidirectional conduction circuit, and the reverse current portion is configured to discharge the input terminal of the source follower circuit after passing through the unidirectional conduction circuit; and
the source follower circuit is configured to generate a detection signal according to a voltage at the input terminal of the source follower circuit and output the detection signal through an output terminal of the source follower circuit.

2. The ultrasonic signal detection circuit according to claim 1, wherein
the unidirectional conduction circuit comprises a diode; and
a first terminal of the diode is connected to the sensing circuit, and a second terminal of the diode is connected to the input terminal of the source follower circuit.

3. The ultrasonic signal detection circuit according to claim 2, wherein
the source follower circuit comprises a first transistor; and
a gate electrode of the first transistor is connected to the input terminal of the source follower circuit, a first terminal of the first transistor is connected to a first voltage supply terminal, and a second terminal of the first transistor is connected to the output terminal of the source follower circuit.

4. The ultrasonic signal detection circuit according to claim 3, wherein
the unidirectional conduction circuit is configured to allow the forward current portion of the alternating current signal to pass through, the first transistor is an N-type transistor, the first terminal of the diode is a positive terminal, and the second terminal of the diode is a negative terminal; or
the unidirectional conduction circuit is configured to allow the reverse current portion of the alternating current signal to pass through, the first transistor is a P-type transistor, the first terminal of the diode is a negative terminal, and the second terminal of the diode is a positive terminal.

5. The ultrasonic signal detection circuit according to claim 1, further comprising a voltage regulation circuit, wherein
the voltage regulation circuit is connected to the input terminal of the source follower circuit and a first control signal terminal; and
the unidirectional conduction circuit is configured to allow the forward current portion of the alternating current signal to pass through, and the voltage regulation circuit is configured to increase the voltage at the input terminal of the source follower circuit by a preset voltage value in response to a control of a first control signal from the first control signal terminal; or
the unidirectional conduction circuit is configured to allow the reverse current portion of the alternating current signal to pass through, and the voltage regulation circuit is configured to decrease the voltage at the input terminal of the source follower circuit by the preset voltage value in response to the control of the first control signal from the first control signal terminal.

6. The ultrasonic signal detection circuit according to claim 5, wherein
the voltage regulation circuit comprises a capacitor; and
a first terminal of the capacitor is connected to the input terminal of the source follower circuit, and a second terminal of the capacitor is connected to the first control signal terminal.

7. The ultrasonic signal detection circuit according to claim 5, further comprising a switching circuit and a reading signal line, wherein
the switching circuit is connected to the output terminal of the source follower circuit and a second control signal terminal; and
the switching circuit is connected to the reading signal line and is configured to control an electric connection/disconnection between the output terminal of the source follower circuit and the reading signal line in response to a control of a second control signal from the second control signal terminal.

8. The ultrasonic signal detection circuit according to claim 7, wherein
the switching circuit comprises a second transistor; and
a gate electrode of the second transistor is connected to the second control signal terminal, a first electrode of the second transistor is connected to the output terminal of the source follower circuit, and a second electrode of the second transistor is connected to the reading signal line.

9. The ultrasonic signal detection circuit according to claim 8, wherein
the voltage regulation circuit is configured to increase the voltage at the input terminal of the source follower circuit by the preset voltage value in response to the control of the first control signal, the second transistor is an N-type transistor, and the first control signal terminal and the second control signal terminal are a same control signal terminal;
or, the voltage regulation circuit is configured to decrease the voltage at the input terminal of the source follower circuit by the preset voltage value in response to the control of the first control signal, the second transistor is a P-type transistor, and the first control signal terminal and the second control signal terminal are a same control signal terminal; and
the preset voltage value is equal to a voltage difference between a high level voltage and a low level voltage of the second control signal.

10. The ultrasonic signal detection circuit according to claim 1, further comprising a reset circuit;
wherein the reset circuit is connected to the input terminal of the source follower circuit, a reset voltage supply terminal and a reset control signal terminal, and is configured to write a reset voltage from the reset voltage supply terminal to the input terminal of the source follower circuit in response to a control of a reset control signal from the reset control signal terminal.

11. The ultrasonic signal detection circuit according to claim 10, wherein
the reset circuit comprises a third transistor; and
a gate electrode of the third transistor is connected to the reset control signal terminal, a first electrode of the third transistor is connected to the input terminal of the source follower circuit, and a second electrode of the third transistor is connected to the reset voltage supply terminal.

12. The ultrasonic signal detection circuit according to claim 1, wherein
the sensing circuit comprises an ultrasonic sensor, a first terminal of the ultrasonic sensor is connected to a second voltage supply terminal, and a second terminal of the ultrasonic sensor is connected to the unidirectional conduction circuit; and
the second voltage supply terminal is configured to provide a reference voltage to the first terminal of the ultrasonic sensor during a signal acquisition phase.

13. The ultrasonic signal detection circuit according to claim 12, wherein
the unidirectional conduction circuit is configured to allow the forward current portion of the alternating current signal to pass through, the reference voltage is equal to V0; or,
the unidirectional conduction circuit is configured to allow the reverse current portion of the alternating current signal to pass through, and the reference voltage is equal to −V0; and
V0 is a forward conduction voltage drop of the unidirectional conduction circuit, where V0 is greater than 0.

14. The ultrasonic signal detection circuit according to claim 12, wherein
the second voltage supply terminal is further configured to provide a driving signal to the first terminal of the ultrasonic sensor during an ultrasonic emission phase.

15. An ultrasonic detection apparatus, comprising a carrier structure and the ultrasonic signal detection circuit according to claim 1, wherein the ultrasonic signal detection circuit is on the carrier structure.

16. An ultrasonic signal detection method, which is based on the ultrasonic signal detection circuit according to claim 1, the ultrasonic signal detection method comprising:
in a signal acquisition phase, generating a piezoelectric signal according to a received ultrasonic echo signal and outputting the piezoelectric signal to the unidirectional conduction circuit, by the sensing circuit, and rectifying, by the unidirectional conduction circuit, the alternating current signal so as to only allow a forward current portion or a reverse current portion of the alternating current signal to pass through; and
in an output phase, generating a detection signal according to a voltage at the input terminal of the source follower circuit, and outputting the detection signal through an output terminal of the source follower circuit, by the source follower circuit.

17. The ultrasonic signal detection method according to claim 16, wherein
the ultrasonic signal detection circuit further comprises a voltage regulation circuit, wherein
the voltage regulation circuit is connected to the input terminal of the source follower circuit and a first control signal terminal; and
the unidirectional conduction circuit is configured to allow the forward current portion of the alternating current signal to pass through, and the voltage regulation circuit is configured to increase the voltage at the input terminal of the source follower circuit by a preset voltage value in response to a control of a first control signal from the first control signal terminal; or
the unidirectional conduction circuit is configured to allow the reverse current portion of the alternating current signal to pass through, and the voltage regulation circuit is configured to decrease the voltage at the input terminal of the source follower circuit by the preset voltage value in response to the control of the first control signal from the first control signal terminal; and
in the signal acquisition phase, the unidirectional conduction circuit only allows the forward current portion of the alternating current signal to pass through, and between the signal acquisition phase and the output phase, the ultrasonic signal detection method further comprises:
in a voltage regulation phase, increasing, by the voltage regulation circuit, the voltage at the input terminal of the source follower circuit by the preset voltage value in response to the control of the first control signal provided by the first control signal terminal; or
in the signal acquisition phase, the unidirectional conduction circuit only allows the reverse current portion of the alternating current signal to pass through, and between the signal acquisition phase and the output phase, the ultrasonic signal detection method further comprises:
in the voltage regulation phase, decreasing, by the voltage regulation circuit, the voltage at the input terminal of the source follower circuit by the preset voltage value in response to the control of the first control signal provided by the first control signal terminal.

18. The ultrasonic signal detection method according to claim 16, wherein
the ultrasonic signal detection circuit further comprises a reset circuit;
wherein the reset circuit is connected to the input terminal of the source follower circuit, a reset voltage supply terminal and a reset control signal terminal, and is configured to write a reset voltage from the reset voltage supply terminal to the input terminal of the source follower circuit in response to a control of a reset control signal from the reset control signal terminal, and
before the signal acquisition phase, the ultrasonic signal detection method further comprises:
in a reset phase, writing, by the reset circuit, the reset voltage provided by the reset voltage supply terminal to the input terminal of the source follower circuit in response to the control of the reset control signal provided by the reset control signal terminal.

19. The ultrasonic signal detection circuit according to claim 6, further comprising a switching circuit and a reading signal line, wherein
the switching circuit is connected to the output terminal of the source follower circuit and a second control signal terminal; and
the switching circuit is connected to the reading signal line and is configured to control an electric connection/disconnection between the output terminal of the source follower circuit and the reading signal line in response to a control of a second control signal from the second control signal terminal.

20. The ultrasonic detection apparatus according to claim 15, wherein
the unidirectional conduction circuit comprises a diode; and
a first terminal of the diode is connected to the sensing circuit, and a second terminal of the diode is connected to the input terminal of the source follower circuit.
